(19) United States
(12) Patent Application Publication
(10) Pub. No.: US 2012/0171474 A1
(43) Pub. Date: Jul. 5, 2012

(54) COATED ARTICLE AND METHOD FOR MAKING SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/166,318

(22) Filed: Jun. 22, 2011

(30) Foreign Application Priority Data
Dec. 31, 2010 (CN) 201010617847.6

(51) Int. Cl. B32B 3/00; C23C 14/06; C23C 14/35; B32B 17/06; B32B 15/04

(52) U.S. Cl. 428/336; 428/426; 428/457; 204/192.15

(57) ABSTRACT

A coated article is provided. The coated article includes a substrate, a hydrophobic layer formed on the substrate. The hydrophobic layer includes a first layer portion formed on the substrate and a second layer portion formed on the first layer portion, the first layer portion is a CN_{y} layer, the second layer portion is a CNₓF_{z} layer, wherein 1≦y≦3, 1≦x≦3, 1≦z≦4. The water contact angle of the hydrophobic layer is more than 110°. The hydrophobic layer has a good chemical stability, high-temperature resistance and a good abrasion resistance, which effectively extends the use time of the coated article. A method for making the coated article is also described there.

### CROSS-REFERENCE TO RELATED APPLICATIONS

The present application is related to co-pending U.S. patent applications (Attorney Docket No. US35723), entitled “COATED ARTICLE AND METHOD FOR MAKING SAME”, by Zhang et al. These applications have the same assignee as the present application and have been concurrently filed herewith. The above-identified applications are incorporated herein by reference.

### BACKGROUND

1. Technical Field

The present disclosure relates to coated articles, particularly to coated articles with hydrophobic effect and a method for making the coated articles.

2. Description of Related Art

Good wetting property is important to solid surfaces. The solid surface, if being hydrophobic, requires that the water contact angle of the solid surface to be greater than 90°. To obtain a hydrophobic surface, the solid surface is usually coated with an organic hydrophobic layer. The organic hydrophobic layer is generally made of polymer material including fluorine and/or silicon. However, organic hydrophobic materials have shortcomings, such as low hardness, poor wear resistance and low heat-resistance temperature, which limits further applications of the organic hydrophobic materials.

Therefore, there is room for improvement within the art.

### BRIEF DESCRIPTION OF THE FIGURE

Many aspects of the coated article and the method for making the coated article can be better understood with reference to the following drawings. The components in the drawings are not necessarily drawn to scale, the emphasis instead being placed upon clearly illustrating the principles of the coated article and the method. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary coated article;

FIG. 2 is a schematic view of a vacuum sputtering device for processing the coated article in FIG. 1.

### DETAILED DESCRIPTION

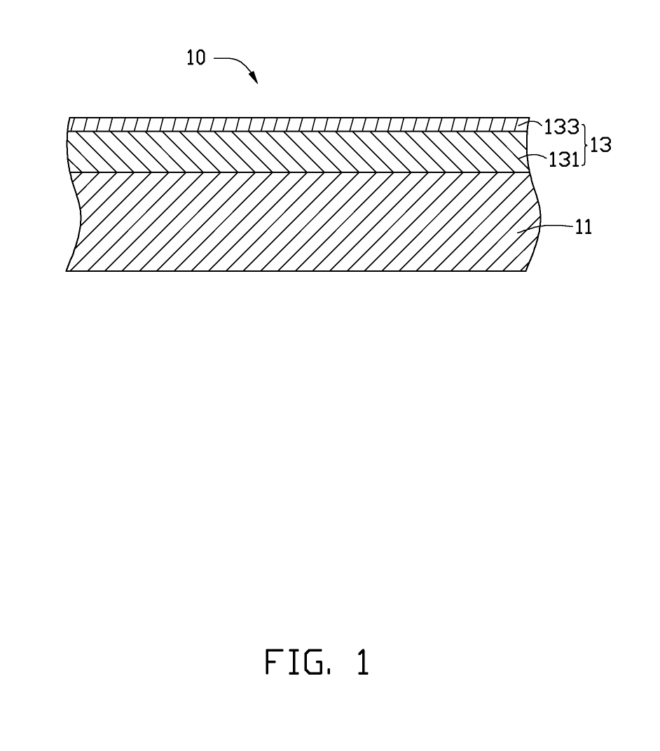

FIG. 1 shows a coated article 10 according to an exemplary embodiment. The coated article 10 includes a substrate 11 and a hydrophobic layer formed on the substrate 11.

The substrate 11 is made of stainless steel or glass.

The hydrophobic layer 13 includes a first layer portion 131 formed on the substrate 11 and a second layer portion 133 formed on the first layer portion 131. The first layer portion 131 is a CN_{y} layer, the second layer portion 133 is a CNₓF_{z} layer, wherein 1≦y≦3, 1≦x≦3, 1≦z≦4. Both of the first layer portion 131 and the second layer portion 133 are amorphous. The hydrophobic layer 13 has a low surface energy and the water contact angle of the hydrophobic layer 13 is more than 110°.

The first layer portion 131 has a thickness of about 100 nm to about 600 nm. The second layer portion 133 has a thickness of about 200 nm to about 400 nm.

A method for making the coated article 10 may include the following steps:

The substrate 11 is pretreated. The pre-treating process may include the following steps:

The substrate 11 is ultrasonically cleaned with alcohol solution in an ultrasonic cleaner (not shown) for about 30 min to 50 min, to remove impurities such as grease or dirt from the substrate 11. Then, the substrate 11 is dried.

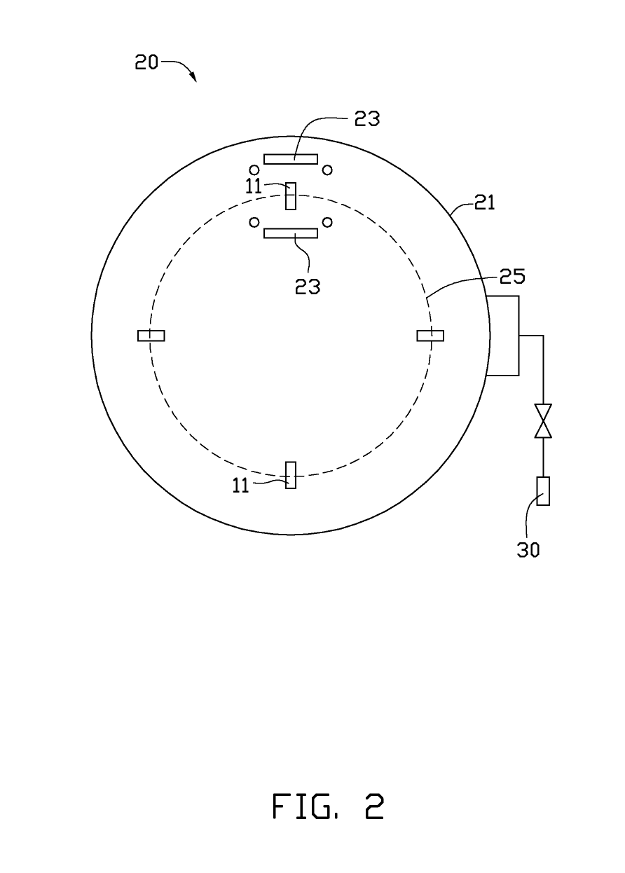

FIG. 2 shows a vacuum sputtering device 20, which includes a vacuum chamber 21 and a vacuum pump 30 connected to the vacuum chamber 21. The vacuum pump 30 is used for evacuating the vacuum chamber 21. The vacuum chamber 21 has a pair of graphite targets 24 and a rotary rack (not shown) positioned therein. The rotary rack holds the substrate 11 to revolve along a circular path 25, the substrate 11 also revolves on its own axis while revolving along the circular path 25.

The substrate 11 is plasma cleaned. The substrate 11 is positioned in the rotary rack of the vacuum chamber 21. The vacuum chamber 21 is then evacuated to 3.0×10⁻⁵ Torr. Argon gas (abbreviated as Ar, having a purity of about 99.999%) is used as sputtering gas and is fed into the vacuum chamber 21 at a flow rate of about 500 standard-state cubic centimeters per minute (sccm). A negative bias voltage in a range of about −100 volts (V) to about −180 V is applied to the substrate 11, then high-frequency voltage is produced in the vacuum chamber 21 and the Ar is ionized to plasma. The plasma then strikes the surface of the substrate 11 to clean the surface of the substrate 11. The plasma cleaning of the substrate 11 takes from about 3 minutes (min) to about 10 min. The plasma cleaning process will enhance the bond between the substrate 11 and the hydrophobic layer 13.

A preliminary layer is vacuum sputtered on the pretreated substrate 11. The preliminary layer is an amorphous CN_{y} layer, wherein 1≦y≦3. Vacuum sputtering of the preliminary layer is implemented in the vacuum chamber 21. The vacuum chamber 21 is evacuated to 8.0×10⁻³ Pa and heated to about 150° C. to about 420° C. Ar is used as sputtering gas and is fed into the vacuum chamber 21 at a flow rate of about 300 sccm to about 380 sccm. Ammonia (NH₃) gas is used as reaction gas and is fed into the vacuum chamber 21 at a flow rate of about 110 sccm to about 300 sccm. The graphite targets 23 are then powered on and set to about 7 kw to about 10 kw. A negative bias voltage of about −50 V to about −300 V is applied to the substrate 11. The depositing of the preliminary layer takes about 20 min to about 60 min. The preliminary layer has a thickness of about 450 nm to about 800 nm.

Fluorinating the preliminary layer to form the complete hydrophobic layer 13. The fluorination treatment was done in a chemical surface treatment furnace (not shown). The substrate 11 coated with the preliminary layer is positioned in the chemical surface treatment furnace. The temperature in the furnace is maintained from about 80° C. to about 120° C. Carbon tetrafluoride (CF₄) gas is fed into the furnace and the CF₄ gas pressure in the furnace is about 10 Pa to about 100 Pa. A radiofrequency electromagnetic field is applied in the region of the substrate 11, which causes CF₄ gas glow discharges. The radiofrequency power density is about 20 W/cm² to about 100 W/cm². The fluorination treatment takes about 10 min to about 120 min.

Fluoride ions from the ionized CF₄ gas can bond with the free dangling bonds of the outmost layer portion of the preliminary layer. The fluorinated portion of the preliminary layer forms the second layer portion 133, while the remaining unfluorinated portion of the preliminary layer forms the first layer portion 131.

### EXAMPLES

Experimental examples of the present disclosure are described as followings.

### Example 1

The vacuum sputtering device 20 used in example 1 was a medium frequency magnetron sputtering device (model No. SM-1100H) manufactured by South Innovative Vacuum Technology Co., Ltd. located in Shenzhen, China.

The substrate 11 was made of glass.

Plasma cleaning: Ar was fed into the vacuum chamber 21 at a flow rate of about 500 sccm. A negative bias voltage of −150 V was applied to the substrate 11. Plasma cleaning of the substrate 11 took about 8 min.

Sputtering to form the preliminary layer: The vacuum chamber 21 was heated to about 300° C. Ar was fed into the vacuum chamber 21 at a flow rate of about 320 sccm. Ammonia gas was fed into the vacuum chamber 21 at a flow rate of about 280 sccm. The power of the graphite targets 23 was 10 kw and a negative bias voltage of −180 V was applied to the substrate 11. The depositing of the preliminary layer took 40 min. The preliminary layer had a thickness of about 450 nm.

Fluorination treatment: The temperature in the furnace was maintained at about 100° C. The CF₄ gas pressure in the furnace was about 11 Pa. The radiofrequency power density was about 55 W/cm². The fluorination treatment took about 80 min.

The first layer portion 131 has a thickness of about 269 nm. The second layer portion 133 has a thickness of about 220 nm. For the first layer portion 131, y is equal to 3. For the second layer portion 133, x is equal to 3 and z is equal to 1.

### Example 2

The vacuum sputtering device 20 used in example 2 was the same in example 1.

The substrate 11 was made of stainless steel.

Plasma cleaning: Ar was fed into the vacuum chamber 21 at a flow rate of about 500 sccm. A negative bias voltage of −180 V was applied to the substrate 11. The plasma cleaning of the substrate 11 took about 10 min.

Sputtering to form the preliminary layer: The vacuum chamber 21 was heated to about 330° C. Ar was fed into the vacuum chamber 21 at a flow rate of about 300 sccm. Ammonia gas was fed into the vacuum chamber 21 at a flow rate of about 220 sccm. The power of the graphite targets 23 was 9 kw and a negative bias voltage of −220 V was applied to the substrate 11. The depositing of the preliminary layer took 55 min. The preliminary layer had a thickness of about 612 nm.

Fluorination treatment: The temperature in the furnace was maintained at about 120° C. The CF₄ gas pressure in the furnace was about 98 Pa. The radiofrequency power density was about 71 W/cm². The fluorination treatment took about 80 min.

The first layer portion 131 has a thickness of about 385 nm. For the first layer portion 131, y is equal to 1. The second layer portion 133 has a thickness of about 356 nm. For the second layer portion 133, x is equal to 1 and z is equal to 3.

### Results of the Above Examples

The water contact angles of the coated articles 10 made in example 1 and 2 were measured using a contact angle measuring instrument (not shown). The water contact angle of the hydrophobic layer 13 in example 1 and 2 is about 110.2° and 116.4°, respectively.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate;
a hydrophobic layer formed on the substrate, the hydrophobic layer includes a first layer portion formed on the substrate and a second layer portion formed on the first layer portion, the first layer portion is a CN_{y} layer, the second layer portion is a CNₓF_{z} layer, wherein 1≦y≦3, 1≦x≦3, 1≦z≦4.

2. The coated article as claimed in claim 1, wherein both of the first layer portion and the second layer portion are amorphous.

3. The coated article as claimed in claim 1, wherein the substrate is made of stainless steel or glass.

4. The coated article as claimed in claim 1, wherein the first layer portion has a thickness of about 100 nm to about 600 nm.

5. The coated article as claimed in claim 1, wherein the second layer portion has a thickness of about 200 nm to about 400 nm.

6. A method for making a coated article, comprising:
providing a substrate;
magnetron sputtering a preliminary layer on the substrate using ammonia gas as reaction gas and graphite targets, the preliminary layer is an amorphous CN_{y} layer, wherein 1≦y≦3; and
fluorinating the preliminary layer to form the complete hydrophobic layer, the hydrophobic layer includes a first layer portion formed on the substrate and a second layer portion formed on the first layer portion, the first layer portion is a CN_{y} layer, the second layer portion is a CNₓF_{z} layer, wherein 1≦y≦3, 1≦x≦3, 1≦z≦4.

7. The method as claimed in claim 6, wherein magnetron sputtering the preliminary layer uses argon gas as sputtering gas, the argon gas has a flow rate of about 300 sccm to about 380 sccm; ammonia gas has a flow rate of about 110 sccm to about 300 sccm; magnetron sputtering the preliminary layer is at a temperature of about 150° C. to about 420° C., the power of the graphite targets is about 7 kw to about 10 kw, a negative bias voltage of about −50 V to about −300 V is applied to the substrate, vacuum sputtering the preliminary layer takes about 20 min to about 60 min.

8. The method as claimed in claim 6, wherein fluorinating the preliminary layer uses carbon tetrafluoride gas and the pressure of the carbon tetrafluoride gas is about 10 Pa to 100 Pa, the radiofrequency power density is about 20 W/cm² to about 100 W/cm², the fluorination temperature is about 80° C. to about 120° C., the fluorination treatment takes about 10 min to about 120 min.

9. The method as claimed in claim 6, wherein the substrate is made of stainless steel or glass.

10. The method as claimed in claim 6, wherein both of the first layer portion and the second layer portion are amorphous.

11. The method as claimed in claim 6, wherein includes the substrate has been pre-cleaned and plasma cleaned prior to magnetron sputtering the preliminary layer on the substrate.
